(19) United States
(12) Patent Application Publication
(10) Pub. No.: US 2025/0279770 A1
(43) Pub. Date: Sep. 4, 2025

(54) METHOD AND DEVICE FOR REDUCING FILTER DELAY SPREAD IN INTERFACE IP

(71) Applicant: STMicroelectronics International N.V., Geneva (CH)

(72) Inventors: Saiyid Mohammad Irshad RIZVI, New Delhi (IN); Ojaswa Deep SINGH, Noida (IN)

(73) Assignee: STMicroelectronics International N.V., Geneva (CH)

(21) Appl. No.: 19/056,472

(22) Filed: Feb. 18, 2025

Related U.S. Application Data
(60) Provisional application No. 63/559,678, filed on Feb. 29, 2024.

(51) Int. Cl. H03K 5/1252; H03K 5/135

(52) U.S. Cl. CPC H03K 5/1252; H03K 5/135

(57) ABSTRACT

An integrated circuit includes a clock input pad that receives a clock signal from an external source. The integrated circuit includes a core logic and an input driver coupled between the clock input pad and the core logic and configured to provide the clock input signal to the core logic. The input driver includes a filter including a plurality of inverter stages coupled in series. The input driver includes an NMOS capacitor coupled between a first pair of the inverter stages. The input driver includes a PMOS capacitor coupled between a second pair of the inverter stages.

### BACKGROUND

### Technical Field

The present disclosure is related to integrated circuit signal interfaces, and more particularly to filters associated with signal interfaces.

### Description of the Related Art

In many electronic systems, an integrated circuit receives signals from an external source and provides signals to the external source. In one example, an integrated circuit receives a clock signal from an external source and provides an output data signal to the external source with timing based on the transitions in the input clock signal.

In one example, an input clock signal is received at a clock input pad of the integrated circuit, is passed through a clock input driver of the integrated circuit, and then is passed to core logic of the integrated circuit. The core logic receives the clock signal and generates and provides an output data signal to a data output driver of the integrated circuit. The data output driver then outputs the data output signal to an I/O pad of the integrated circuit.

In order to ensure proper timing, there may be various timing specifications. A timing specification may ensure that when the rising edge of the falling edge of the clock signal arrives at the clock input driver, that the total delay of the clock input driver, the core logic, and the data output driver should be within some limit. This may correspond to a data valid time or total loop delay.

Another aspect of the interface is to reject transient pulses in either the input clock signal or the input data signal. In other words, an interface may filter out signal features with very short delays so that such transient signal features are not treated as legitimate clock transitions or data transitions.

Furthermore, because of process, voltage, or temperature variations, there can be different delays in rising edges and falling edges of the input clock signal or input data signals. Additionally, based on process, voltage, or temperature variations, in some cases rising edges may have a greater delay than falling edges, and in other cases falling edges may have a greater delay than rising edges. However, in some instances it may be beneficial to help ensure that one type of edge has a greater delay than another type of etch.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor's approach to the particular problem, which, in and of itself, may also be inventive.

### SUMMARY

Embodiments of the present disclosure provide an integrated circuit signal interface that helps to ensure that data valid times are met, transient signals are filtered, and rising and falling edge delays are controlled in a desired manner. Embodiments of the present disclosure provide a filter in an input driver that assists in accomplishing the above-mentioned benefits. The filter has a first stage including an NMOS capacitor that compensates for the driver's NMOS variation. The filter has a second stage that includes a PMOS capacitor that compensates for the driver's PMOS variation.

In one embodiment, the filter includes a plurality of inverters coupled together in series. The NMOS capacitor is coupled between a first pair of the inverters. The PMOS capacitor is coupled between a second pair of the inverters.

In one embodiment, an integrated circuit includes a first pad, a first input driver coupled to the first pad, and a first filter in the first input driver. The first filter includes a first inverter, a second inverter coupled in series with the first inverter, and a third inverter coupled in series with the second inverter. The first filter includes a first MOS capacitor of a first conductivity type coupled between the first inverter and the second inverter. The first filter includes a second MOS capacitor of a second conductivity type coupled between the second inverter and the third inverter.

In one embodiment, a method includes receiving, with a first driver of an integrated circuit, a first signal from a first pad of the integrated circuit and filtering rising edge transients from the first signal with a first RC filter positioned between a first inverter and a second inverter of the driver. The method includes filtering falling edge transients from the first signal with a second RC filter positioned between the second inverter and a third inverter and providing the first signal from the first driver to a core logic of the integrated circuit.

In one embodiment, a method includes receiving, with a driver, a first signal from a first pad of an integrated circuit and passing the first signal through a first MOS capacitor of a first conductivity type positioned between a first inverter and a second inverter of the driver. The method includes passing the first signal through a second MOS capacitor of a second conductivity type positioned between a third inverter and a fourth inverter of the driver and passing the first signal from the first driver to a core logic of the integrated circuit.

### BRIEF DESCRIPTION OF THE SEVERAL VIEWS OF THE DRAWINGS

Reference will now be made by way of example only to the accompanying drawings. In the drawings, identical reference numbers identify similar elements or acts. In some drawings, however, different reference numbers may be used to indicate the same or similar elements. The sizes and relative positions of elements in the drawings are not necessarily drawn to scale. For example, the shapes of various elements and angles are not necessarily drawn to scale, and some of these elements may be enlarged and positioned to improve drawing legibility.

FIG. 1A is a block diagram of an integrated circuit, in accordance with one embodiment.

FIG. 1B is a block diagram of signals associated with the integrated circuit, in accordance with one embodiment.

FIG. 2 is a block diagram of a filter of an input driver of an integrated circuit, in accordance with one embodiment.

FIG. 3 is a schematic diagram of a filter of an input driver of an integrated circuit, in accordance with one embodiment.

FIG. 4 is a graph illustrating a signal received at a pad of an integrated circuit, in accordance with one embodiment.

FIG. 5 is a flow diagram of a method for operating an integrated circuit, in accordance with one embodiment.

FIG. 6 is a flow diagram of a method for operating an integrated circuit, in accordance with one embodiment.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. In other instances, well-known algorithms associated with facial recognition, facial detection, and facial authentication have not been shown or described in detail, to avoid unnecessarily obscuring descriptions of the embodiments. Further, well-known structures associated with the time of flight sensor and inertial measurement units have not been shown or described in detail, to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is as “including, but not limited to.” Further, the terms “first,” “second,” and similar indicators of sequence are to be construed as interchangeable unless the context clearly dictates otherwise.

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly dictates otherwise.

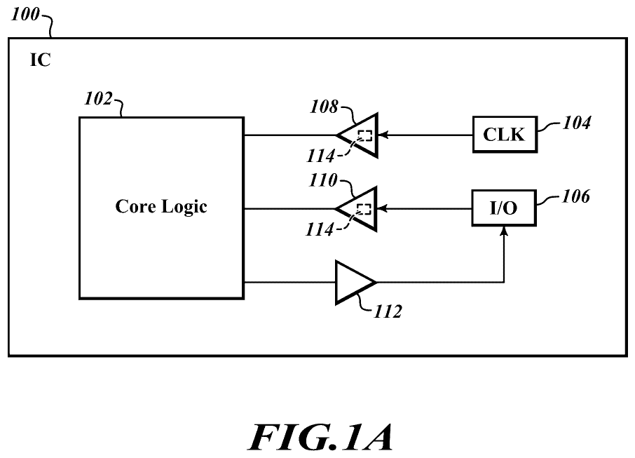

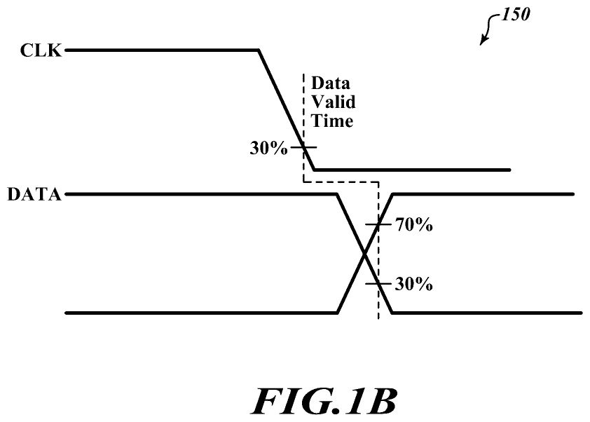

FIG. 1A is a block diagram of an integrated circuit 100, in accordance with one embodiment. As will be set forth in more detail below, the components of the integrated circuit 100 cooperate to ensure that a loop delay specification is met, transient pulses are effectively filtered, and spreads in delays or skews in rising and falling edges of input signals are low.

In one embodiment, the integrated circuit 100 includes a core logic 102. The core logic 102 can include a plurality of transistors coupled together in complex arrangements. The transistors can process input signals and can generate output signals based on the input signals. Furthermore, the transistors of the core logic can execute software instructions or implement other protocols.

In one embodiment, the transistors of the core logic are relatively small so that a large number of transistors can be utilized in a relatively small area. This helps to ensure that the core logic 102 has powerful processing capabilities. Because the transistors of the core logic 102 are small, the transistors of the core logic 102 may have low voltage ratings. In other words, the transistors of the core logic can only withstand relatively low voltage differences between any two terminals without being damaged.

The integrated circuit 100 includes a clock input pad 104. The clock input pad 104 is a terminal that receives a clock signal CLK from a source external to the integrated circuit 100. For example, the clock input terminal may receive the clock signal CLK from a second integrated circuit. The integrated circuit 100 may utilize the clock signal CLK to control the timing of receiving data from the external integrated circuit and of sending data to the external integrated circuit.

The integrated circuit 100 includes a clock input driver 108 coupled between the clock input pad 104 and the core logic 102. One function of the clock input driver is to ensure that the clock signal CLK is in a form that can be safely and accurately received by the core logic 102. For example, if the clock signal CLK has higher voltages than are safe for the transistors of the core logic 102, then the clock input driver 108 may change the voltage levels of the clock signal CLK to a lower value that can be safely received by the transistors of the core logic 102. In another example, the clock signal CLK may have voltage values that are lower than desired. The clock input driver can bring the voltage levels of the clock signal CLK to a level that can be properly utilized by the core logic 102.

Another function of the clock input driver 108 is to filter out noise or transient signals from the clock signal CLK. For example, it is possible that the clock signal CLK received at the clock input pad 104 may occasionally have transient spikes or dips. It is beneficial that these spikes and dips are not interpreted as legitimate rising edges or falling edges of the clock signal CLK. Accordingly, one function of the clock input driver 108 is to filter out such transient signals.

Another function of the clock input driver 108 is to manage the spread in the delays of both the rising edge of the falling edge of the clock signal CLK. As described previously, based on variations in the process (manufacturing of the integrated circuit), voltage, and temperature, there may be variations in the delays in either or both of the rising edge of falling edge of the clock signal CLK. Maintenance of the positive skew between the two delay edges could lead to a high spread one edge. The delay spread of an edge corresponds to the difference between the largest possible delay due to variations and the smallest possible delay due to variations. High spreads can lead to failure/marginality in the total loop time (data valid time). Furthermore, in some cases it is beneficial to ensure that the rising edge delay is greater than the falling edge delay.

The clock input driver 108 includes a filter 114 in order to help perform the functions described above. The filter 114 helps manage staying within the total loop time, filtering out transient pulses, and managing the edge delay spread across process, voltage, and temperature variations.

One possible implementation of the filter includes a first inverter and a second inverter coupled together in series. The input of the first inverter receives the clock signal CLK. The output of the second inverter provides the clock signal CLK to the core logic. An RC filter can be implanted with a first resistor in the NMOS current path of the first inverter, a second resistor coupled between the output of the first inverter and the input of the second inverter, and an NMOS capacitor coupled between the second resistor and the input of the second inverter. Such an implementation may successfully filter out transient pulses within specification, maintain the rising edge delay greater than the falling edge delay across variations in process, voltage, and temperature, maintain a low spread of the falling edge delay, and provide easy controllability of the rising edge delay. The NMOS capacitor compensates the process variation of the inverter's NMOS reducing falling edge delay. However, this implementation has the possible drawback of a high spread of the rising edge delay changing only the falling edge delay may not be possible.

Another possible implementation of a filter differs from the possible implementation above in that a PMOS capacitor is also coupled between the second resistor and the input of the second inverter. This can have the additional benefits of a reduced spread of the rising edge delay, the PMOS capacitor compensates for process variation of the inverter's PMOS, and forming capacitors with both PMOS and NMOS partially compensates for both PMOS and NMOS of the second inverter stage. However, this has the drawbacks of the spread of the falling edge delay be greater than in the previous implementation. Furthermore, changing only the falling edge delay may remain in possible.

In one embodiment, the filter 114 is implemented in a manner that improves on both of the previously mentioned possible solutions. In particular, in one embodiment the filter 114 includes several pairs of inverters connected in series. A first RC filter is implemented between a first pair of the inverters with a first resistor, a second resistor, and an NMOS capacitor as described above. A second RC filter is implemented between a second pair of the inverters with a third resistor coupled in the NMOS branch of the first inverter of the second pair, a fourth resistor coupled between the output of the first inverter of the second pair in the input of the second inverter of the second pair, and a PMOS capacitor coupled between the fourth resistor and the input of the second inverter of the second pair.

This implementation improves on the two previously mentioned possible implementations. In particular, transient pulses are filtered out. The rising edge delay is maintained is greater than the falling edge delay across pressure, voltage, and temperature variations. There is a lower spread of both the rising edge delay and the falling edge delay. The rising edge delay and the falling edge delay can be controlled separately. The first RC filter's NMOS capacitor compensates for NMOS inverter variation. The second RC filter's PMOS capacitor compensates for inverter PMOS variation.

In one embodiment, the integrated circuit includes a second pad 106. The second pad 106 is an I/O pad. The I/O pad can receive data from the external integrated circuit and can provide data to the external integrated circuit.

In one embodiment, the integrated circuit includes an input data driver 110. When data is received at the I/O pad 106, the data is passed to the input data driver 110. The input data driver 110 performs the filtering, delay, and transformation functions described in relation to the clock input driver 108. The input data driver 110 provides the input data to the core logic 102.

In one embodiment, the input data driver 110 includes a second filter 114. The second filter 114 can be substantially identical to the first filter 114 of the input data driver 108, as described above. In particular, the filter 114 of the input data driver 110 can include a first RC filter including an NMOS capacitor coupled between a first pair of inverters. The filter 114 of the input data driver 110 can include a second RC filter including a PMOS capacitor coupled between a second pair of inverters.

In one embodiment, the integrated circuit 110 includes an output data driver 112. When the core logic 102 receives the clock signal CLK and processes the clock signal CLK, the core logic 102 may output data. The output data is provided to the output data driver 112, and from the output data driver 112 to the I/O pad 106. While the input data driver 110 and the output data driver 112 are shown as separate circuits, in practice, the input data driver 110 and the output data driver 112 may correspond to a single transmitter circuit that can both receive data from the pad 106 and provide data to the pad 106.

As described previously, it is beneficial if the clock signal CLK and the data output signal fall within a data valid time (or total loop delay). FIG. 1B is a graph 150 illustrating the input clock signal CLK and the output data signal DATA. The data valid time, in one example, corresponds to a delay between a falling edge threshold (e.g., 30% of VDD) of the clock signal CLK and the rising edge of the data signal DATA reaching 70% of VDD (or the falling edge of the data signal DATA reaching 30% of VDD). Other thresholds can be utilized.

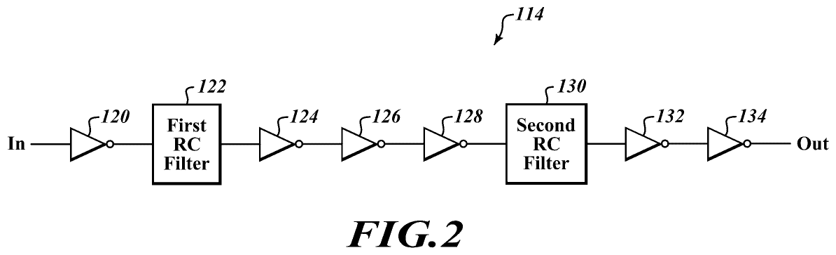

FIG. 2 is a schematic diagram of a filter 114, in accordance with one embodiment. The filter 114 of FIG. 2 is one example of a filter 114 of the clock input driver 108 of a filter 114 of the data input driver 110 of FIG. 1A.

The filter 114 includes a plurality of inverters 120, 124, 126, 128, 132, and 134 connected in series. The filter 114 includes a first RC filter stage 122 coupled between a first pair of inverters 120 and 124. The filter 114 includes a second RC filter stage 130 coupled between a second pair of inverters 128 and 132.

In one embodiment, the first RC filter 122 includes a first MOS capacitor of a first conductivity type. The second RC filter 130 includes a second MOS capacitor of a second conductivity type opposite to the first conductivity type. In one example, the first MOS capacitor is an NMOS capacitor, while the second MOS capacitor is a PMOS capacitor.

When an input signal is received at the input of the inverter 120, the input signal is inverted by the inverter 120 and is passed through the first RC filter 122. The input signal is then inverted three more times by the inverters 124, 126, and 128. The input signal is then passed through the second RC filter 130. Finally, the input signal is inverted twice more by the inverters 132 and 134. Because the input signal is passed through an even number of inverters, a pulse received at the input will have a same logical value when passed to the output. Various other configurations of a filter 114 can be utilized without departing from the scope of the present disclosure.

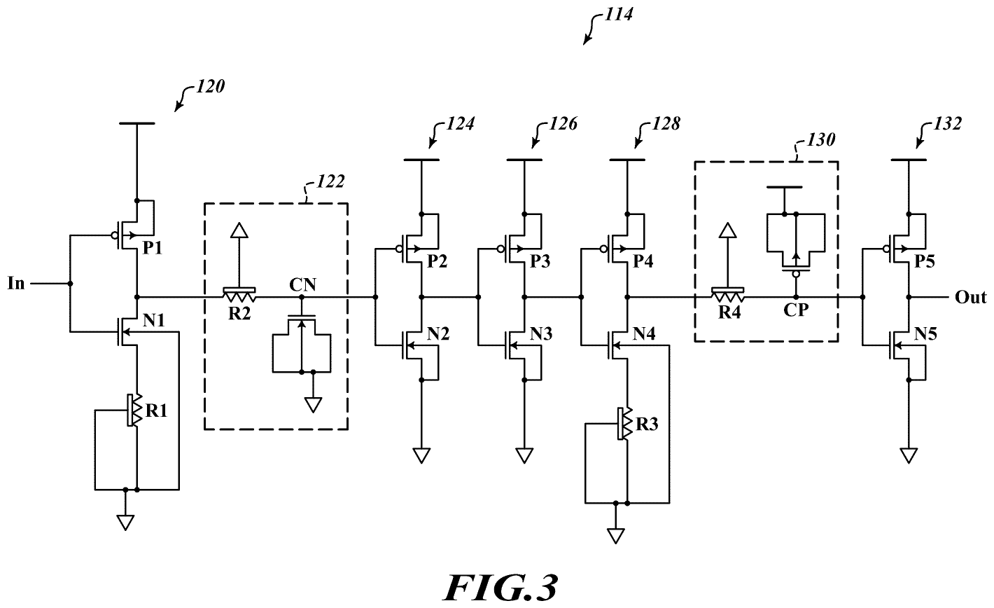

FIG. 3 is a schematic diagram of a filter 114, in accordance with some embodiments. The filter 114 of FIG. 3 is one example of a filter 114 of FIG. 1A.

The filter 114 includes a first inverter 120. The first inverter 120 includes a first PMOS transistor P1 and the first NMOS transistor N1. The gate terminals of the transistors P1 and N1 correspond to the input of the inverter 120. The drain terminals of the transistors P1 and N1 correspond to the output of the inverter 120. The source terminal of the inverter 120 is coupled to the high supply voltage VDD. A three-terminal resistor R1 is coupled between the source terminal of the transistor N1 and ground. The body terminal of the transistor P1 is coupled to VDD. The body terminal of the transistor N1 is coupled to ground.

In one embodiment, the resistor R1 is a three-terminal resistor. In one embodiment, the resistor R1 includes a resistive material such as polysilicon layer on top of the semiconductor substrate at the region of the transistor N1. As will be set forth in more detail below, the resistor R1 may be considered part of a first RC filter 122.

The filter 114 includes a second inverter 124 having a PMOS transistor P2 and an NMOS transistor N2, coupled substantially the same as the transistors P1 and N1 of the inverter 120, except that a resistor is not present between the source terminal of the NMOS transistor N2 and ground.

The filter 114 includes an inverter 126. The inverter 126 includes a PMOS transistor P3 and NMOS transistor N3. The PMOS transistor P3 and the NMOS transistor N3 are coupled in a same manner as the transistors P2 and N2 of the inverter 124.

The filter 114 includes an inverter 128. Inverter 128 includes a PMOS transistor P4, an NMOS transistor N4, and a three-terminal resistor R3. The transistor P4, the transistor N4, and the resistor R3 are coupled in a same manner as the transistors P1 and N1 and the resistor R1 of the inverter 120.

The filter 114 includes an inverter 132. The inverter 132 includes a PMOS transistor P5 and an NMOS transistor N5. The PMOS transistor P5 and the NMOS transistor N5 are coupled in a same manner as the transistors P2 and N2 of the inverter 124. Though not shown in FIG. 3, the filter 114 may include yet another inverter 134 coupled between the inverter 132 and the output of the filter 114.

The filter 114 includes a first RC filter 122 coupled between the output of the inverter 120 and the input of the inverter 124. The first RC filter 122 includes a three-terminal resistor R2 coupled between the output of the inverter 120 and the input of the inverter 124. The RC filter 122 includes an NMOS capacitor CN coupled to the input of the inverter 124.

In one embodiment, the NMOS capacitor CN includes a gate terminal coupled between the resistor R2 and the input of the inverter 124. The gate terminal is a first capacitor terminal of the NMOS capacitor CN. The NMOS capacitor CN includes a body terminal, a source terminal, and a drain terminal each coupled to ground. The source terminal, the drain terminal and the body terminal of the NMOS capacitor CN correspond to a second capacitor terminal of the NMOS capacitor CN. Though not shown, the resistor R1 may be considered part of the RC filter 122.

The filter 114 includes a second RC filter 130 coupled between the output of the inverter 128 and the input of the inverter 132. The second RC filter 130 includes a three-terminal resistor R4 coupled between the output of the inverter 128 and the input of the inverter 132. The RC filter 130 includes a PMOS capacitor CP coupled to the input of the inverter 132.

In one embodiment, the PMOS capacitor CP includes a gate terminal coupled between the resistor R4 and the input of the inverter 132. The gate terminal is a first capacitor terminal of the PMOS capacitor CP. The PMOS capacitor CP includes a body terminal, a source terminal, and a drain terminal each coupled to the high supply voltage VDD. The source terminal, drain terminal and body terminal of the PMOS capacitor CP correspond to a second capacitor terminal of the PMOS capacitor CP. Though not shown, the resistor R3 may be considered part of the RC filter 130.

When a rising edge signal is received at the input of the filter 114, the transistor N1 becomes conductive, thereby coupling the output of the inverter 120 to ground via the resistor R1. The result is that the input terminal of the inverter 124 is coupled to ground through the resistors R1 and R2. If the NMOS capacitor CN was previously at a high voltage, then before the input of the transistor 124 can transition low (corresponding to an inversion of the rising edge pulse received at the input of the inverter 120) the gate terminal of the capacitor CN will be discharged to ground via the resistors R2 and R1.

The amount of time required for this discharge is based on the capacitance of the capacitor CN and the resistances of the resistors R1 and R2. If the rising edge pulse is of a shorter duration than the discharge time, then the rising edge pulse will be filtered out. In other words, the input of the inverter 124 will not change and the pulse will not be propagated through the remaining inverters. Accordingly, rising edge transient signals are filtered by the filter 122. Because the capacitor CN is an NMOS capacitor, variations in the NMOS transistors of the inverters of the filter 114 due to process, temperature, and voltage, are taken into account by the NMOS capacitor CN.

If a falling edge pulse is received at the input of the inverter 120, the gate terminal of the transistor CN will be charged from ground to VDD via the resistor R2, without influence of the resistor R1. Accordingly, the filter 120 performs a smaller filtering function for falling edge pulse is received at the input of the inverter 120. In other words, if the only the filter 122 was present, then charge time from ground to VDD may not be sufficient to filter out transient falling edge pulses.

If a falling edge pulse is propagated through the filter 122 and through the inverter 124, then the output of the inverter 124 will go low, the output of the inverter 126 will go high. When the output of the inverter 126 goes high, the NMOS transistor N4 of the inverter 128 will turn on. If the gate terminal of the PMOS capacitor CP is charged to VDD, then the capacitor CP will need to discharge to ground via the resistors R4 and R3 before the input of the inverter 132 goes low.

The amount of time required for this discharge is based on the capacitance of the capacitor CP and the resistances of the resistors R3 and R4. If the falling edge pulse is of a shorter duration than the discharge time, then the falling edge pulse will be filtered out by the RC filter 130. In other words, the input of the inverter 132 will not change and the pulse will not be propagated through to the output of the filter 114. Accordingly, falling edge transitory signals are filtered by the filter 130. Because the capacitor CP is a PMOS capacitor, variations in the PMOS transistors of the inverters of the filter 114 due to process, temperature, and voltage, are compensated by the PMOS capacitor CP.

In one embodiment, the rising edge delay is controlled by the resistor R1. In one embodiment, the falling edge delay is controlled by the resistor R3. The combination of the first RC filter 122 including the NMOS capacitor CN and the RC filter 130 including the PMOS capacitor CP helps ensure that the spread in rising edge delays due to variations and the spread in falling edge delays due to variations are both relatively small. Furthermore, this combination helps ensure that the rising edge delay is greater than the falling edge delay, in accordance with one embodiment. Other configurations of a filter 114 can be utilized without departing from the scope of the present disclosure.

In one nonlimiting example, the filter 114 may be designed to filter out transient signals smaller than 50 ns. The minimum rising edge delay is about 54 ns. The maximum rising edge delay is about 169 ns. The minimum falling edge delay is about 52 ns. The maximum falling edge delay is about 153 ns. Accordingly, the spread in delays of the rising edge (169 ns-54 ns=115 ns) is greater than the spread in delays of the falling edge (153 ns-52 ns=101 ns). Furthermore, rising edge or falling edge transients with a duration less than 50 ns will be filtered out as the minimum rising edge delay is 54 ns and the minimum falling edge delay is 52 ns. Additionally, the NMOS capacitor CN of the first RC filter stage 122 compensates for NMOS inverter variation, while the PMOS capacitor CP of the second RC filter stage 130 compensates for PMOS inverter variation.

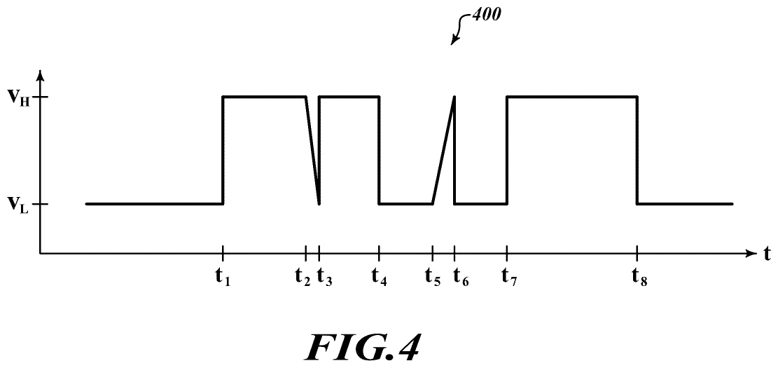

FIG. 4 is a graph of 400 of an input signal, in accordance with one embodiment. The graph 400 can be sold illustrating which edges are filtered, and which edges are propagated. At time T1, the input signal goes from a low voltage VL (i.e., ground) to a high voltage VH (i.e., VDD). This rising edge signal remains high for a sufficient length of time to pass the filter 114.

Between times T2 and T3, a falling edge transient occurs. This transient is not of sufficient duration and is filtered out by the filter 114.

At time T4, a falling edge occurs. This falling edge remains low for a sufficient length of time to pass the filter 114.

Between times T5 and T6, a transient rising edge occurs. This transient is not of sufficient duration and is filtered out by the filter 114.

At time T7, a rising edge occurs and is of sufficient duration to pass the filter 114. At time T8, a falling edge occurs in this of sufficient duration to pass the filter 114.

While FIG. 4 illustrates the true edges of the signal as being substantially vertical, in practice, there will be a delay or skew in the transition such that the rising and falling edges will be sloped, as described previously.

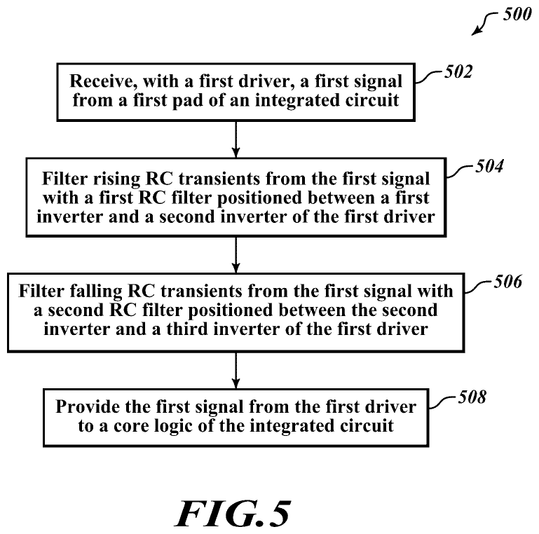

FIG. 5 is a flow diagram of a method 500 for operating an integrated circuit, in accordance with one embodiment. The method 500 can utilize components, systems, and processes described in relation to FIGS. 1A-4. At 502, the method 500 includes receiving, with a first driver of an integrated circuit, a first signal from a first pad of the integrated circuit. At 504, the method 500 includes filtering rising edge transients from the first signal with a first RC filter positioned between a first inverter and a second inverter of the driver. At 506, the method 500 includes filtering falling edge transients from the first signal with a second RC filter positioned between the second inverter and a third inverter. At 508, the method 500 includes providing the first signal from the first driver to a core logic of the integrated circuit.

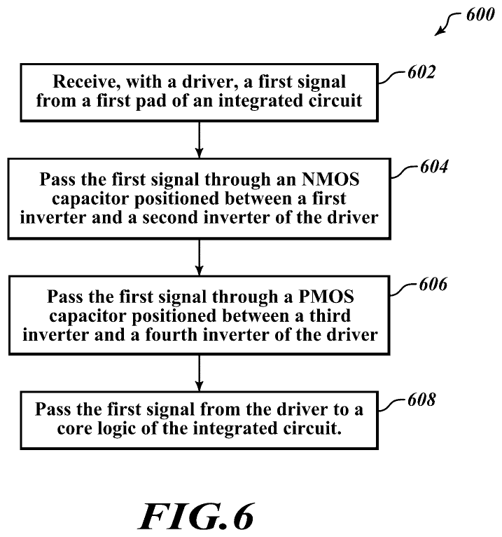

FIG. 6 is a flow diagram of a method 600 for operating an integrated circuit, in accordance with one embodiment. The method 600 can utilize components, systems, and processes described in relation to FIGS. 1A-4. At 602, the method 600 includes receiving, with a driver, a first signal from a first pad of an integrated circuit. At 604, the method 600 includes passing the first signal through a first MOS capacitor of a first conductivity type positioned between a first inverter and a second inverter of the driver. At 606, the method 600 includes passing the first signal through a second MOS capacitor of a second conductivity type positioned between a third inverter and a fourth inverter of the driver. At 608, the method 600 includes passing the first signal from the first driver to a core logic of the integrated circuit.

In one embodiment, an integrated circuit includes a first pad, a first input driver coupled to the first pad, and a first filter in the first input driver. The first filter includes a first inverter, a second inverter coupled in series with the first inverter, and a third inverter coupled in series with the second inverter. The first filter includes a first MOS capacitor of a first conductivity type coupled between the first inverter and the second inverter. The first filter includes a second MOS capacitor of a second conductivity type coupled between the second inverter and the third inverter.

In one embodiment, the first filter includes a first RC filter including the first MOS capacitor and a first resistor coupled between a source terminal of a first NMOS transistor of the first inverter stage and ground.

In one embodiment, the first RC filter includes a second resistor coupled to the first MOS capacitor.

In one embodiment, the first filter includes a second RC filter including the second MOS capacitor and a third resistor coupled between a source terminal of a second NMOS transistor of the second inverter stage and ground.

In one embodiment, the second RC filter includes a fourth resistor coupled to the second MOS capacitor.

In one embodiment, the first MOS capacitor is an NMOS capacitor including a gate terminal corresponding to a first capacitor terminal of the NMOS capacitor. The NMOS capacitor includes a source terminal, a drain terminal, and a body terminal coupled together as a second capacitor terminal of the NMOS capacitor.

In one embodiment, the second capacitor terminal of the NMOS transistor is coupled to ground.

In one embodiment, the second MOS capacitor is a PMOS capacitor including a gate terminal corresponding to a first capacitor terminal of the PMOS capacitor. The PMOS capacitor includes a source terminal, a drain terminal, and a body terminal coupled together as a second capacitor terminal of the PMOS capacitor.

In one embodiment, the second capacitor terminal of the PMOS transistor is coupled to a high supply voltage.

In one embodiment, the first pad is a clock input pad and the first input driver is a clock input driver.

In one embodiment, the integrated circuit includes a second pad corresponding to an I/O pad, a second input driver coupled between the I/O pad and the core logic, and a second filter in the second input driver. The second filter includes a fourth inverter, a fifth inverter coupled in series with the fourth inverter, and a sixth inverter coupled in series with the fifth inverter. The second filter includes a third MOS capacitor of the first conductivity type coupled between the fourth inverter and the fifth inverter and a fourth MOS capacitor of the second conductivity type coupled between the fifth inverter and the sixth inverter.

In one embodiment, the first filter includes a fourth inverter coupled in series between the first inverter and the second inverter. The first MOS capacitor is coupled to an input of the fourth inverter. The first filter includes a fifth inverter coupled in series between the fourth inverter and the second inverter, wherein the second MOS capacitor is coupled to an input of the third inverter.

In one embodiment, the first filter includes a sixth inverter having an input coupled to an output of the third inverter.

In one embodiment, a method includes receiving, with a first driver of an integrated circuit, a first signal from a first pad of the integrated circuit and filtering rising edge transients from the first signal with a first RC filter positioned between a first inverter and a second inverter of the driver. The method includes filtering falling edge transients from the first signal with a second RC filter positioned between the second inverter and a third inverter and providing the first signal from the first driver to a core logic of the integrated circuit.

In one embodiment, the first RC filter includes an NMOS capacitor having a first capacitor terminal coupled to an input of the second inverter and a second capacitor terminal coupled to ground. In one embodiment, the first RC filter includes a first resistor coupled between an output of the first inverter and the first capacitor terminal and a second resistor coupled between a first NMOS transistor of the first inverter and ground.

In one embodiment, the second RC filter includes a PMOS capacitor having a first capacitor terminal coupled to an input of the third inverter and a second capacitor terminal coupled to a high supply voltage.

In one embodiment, the method includes receiving, with a second driver of the integrated circuit, a second signal from a second pad of the integrated circuit and filtering rising edge transients from the second signal with a first third filter positioned between a fourth inverter and a fifth inverter of the second driver. In one embodiment, the method includes filtering falling edge transients from the second signal with a fourth RC filter positioned between the fifth inverter and a sixth inverter and providing the second signal from the second driver to the core logic of the integrated circuit.

In one embodiment, the first signal is a clock signal and the second signal is a data signal.

In one embodiment, a method includes receiving, with a driver, a first signal from a first pad of an integrated circuit and passing the first signal through a first MOS capacitor of a first conductivity type positioned between a first inverter and a second inverter of the driver. The method includes passing the first signal through a second MOS capacitor of a second conductivity type positioned between a third inverter and a fourth inverter of the driver and passing the first signal from the first driver to a core logic of the integrated circuit.

In one embodiment, the method includes outputting passing a second signal from the core logic to a second pad of the integrated circuit responsive to a transition in the first signal.

In one embodiment, the first MOS capacitor is an NMOS capacitor and the second MOS capacitor is a PMOS capacitor.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An integrated circuit, comprising:
a first pad;
a first input driver coupled to the first pad; and
a first filter in the first input driver, the first filter including:
a first inverter;
a second inverter coupled in series with the first inverter;
a third inverter coupled in series with the second inverter;
a first MOS capacitor of a first conductivity type coupled between the first inverter and the second inverter; and
a second MOS capacitor of a second conductivity type coupled between the second inverter and the third inverter.

2. The integrated circuit of claim 1, wherein the first filter includes a first RC filter including:
the first MOS capacitor; and
a first resistor coupled between a source terminal of a first NMOS transistor of the first inverter stage and ground.

3. The integrated circuit of claim 2, wherein the first RC filter includes a second resistor coupled to the first MOS capacitor.

4. The integrated circuit of claim 3, wherein the first filter includes a second RC filter including:
the second MOS capacitor; and
a third resistor coupled between a source terminal of a second NMOS transistor of the second inverter stage and ground.

5. The integrated circuit of claim 4, wherein the second RC filter includes a fourth resistor coupled to the second MOS capacitor.

6. The integrated circuit of claim 1, wherein the first MOS capacitor is an NMOS capacitor including:
a gate terminal corresponding to a first capacitor terminal of the NMOS capacitor;
a source terminal, a drain terminal, and a body terminal coupled together as a second capacitor terminal of the NMOS capacitor.

7. The integrated circuit of claim 6, wherein the second capacitor terminal of the NMOS transistor is coupled to ground.

8. The integrated circuit of claim 6, wherein the second MOS capacitor is a PMOS capacitor including:
a gate terminal corresponding to a first capacitor terminal of the PMOS capacitor;
a source terminal, a drain terminal, and a body terminal coupled together as a second capacitor terminal of the PMOS capacitor.

9. The integrated circuit of claim 8, wherein the second capacitor terminal of the PMOS transistor is coupled to a high supply voltage.

10. The integrated circuit of claim 1, wherein the first pad is a clock input pad and the first input driver is a clock input driver.

11. The integrated circuit of claim 10, comprising:
a second pad corresponding to an I/O pad;
a second input driver coupled between the I/O pad and the core logic; and
a second filter in the second input driver, the second filter including:
a fourth inverter;
a fifth inverter coupled in series with the fourth inverter;
a sixth inverter coupled in series with the fifth inverter;
a third MOS capacitor of the first conductivity type coupled between the fourth inverter and the fifth inverter; and
a fourth MOS capacitor of the second conductivity type coupled between the fifth inverter and the sixth inverter.

12. The integrated circuit of claim 1, wherein the first filter includes:
a fourth inverter coupled in series between the first inverter and the second inverter, wherein the first MOS capacitor is coupled to an input of the fourth inverter; and
a fifth inverter coupled in series between the fourth inverter and the second inverter, wherein the second MOS capacitor is coupled to an input of the third inverter.

13. The integrated circuit of claim 12, wherein the first filter includes a sixth inverter having an input coupled to an output of the third inverter.

14. A method, comprising:
receiving, with a first driver of an integrated circuit, a first signal from a first pad of the integrated circuit;
filtering rising edge transients from the first signal with a first RC filter positioned between a first inverter and a second inverter of the driver;
filtering falling edge transients from the first signal with a second RC filter positioned between the second inverter and a third inverter; and
providing the first signal from the first driver to a core logic of the integrated circuit.

15. The method of claim 14, wherein the first RC filter includes an NMOS capacitor having a first capacitor terminal coupled to an input of the second inverter and a second capacitor terminal coupled to ground.

16. The method of claim 15, wherein the first RC filter includes:
a first resistor coupled between an output of the first inverter and the first capacitor terminal; and
a second resistor coupled between a first NMOS transistor of the first inverter and ground.

17. The method of claim 16, wherein the second RC filter includes a PMOS capacitor having a first capacitor terminal coupled to an input of the third inverter and a second capacitor terminal coupled to a high supply voltage.

18. The method of claim 14, comprising:
receiving, with a second driver of the integrated circuit, a second signal from a second pad of the integrated circuit;
filtering rising edge transients from the second signal with a first third filter positioned between a fourth inverter and a fifth inverter of the second driver;
filtering falling edge transients from the second signal with a fourth RC filter positioned between the fifth inverter and a sixth inverter; and
providing the second signal from the second driver to the core logic of the integrated circuit.

19. The method of claim 18, wherein the first signal is a clock signal and the second signal is a data signal.

20. A method, comprising:
receiving, with a driver, a first signal from a first pad of an integrated circuit;
passing the first signal through a first MOS capacitor of a first conductivity type positioned between a first inverter and a second inverter of the driver;
passing the first signal through a second MOS capacitor of a second conductivity type positioned between a third inverter and a fourth inverter of the driver; and
passing the first signal from the first driver to a core logic of the integrated circuit.

21. The method of claim 20, comprising outputting passing a second signal from the core logic to a second pad of the integrated circuit responsive to a transition in the first signal.

22. The method of claim 20 wherein the first MOS capacitor is an NMOS capacitor, wherein the second MOS capacitor is a PMOS capacitor.
